(19) United States
(12) Patent Application Publication
(10) Pub. No.: US 2025/0210461 A1
(43) Pub. Date: Jun. 26, 2025

(54) PACKAGES WITH DOUBLE-SIDE METAL PILLARS AND THE METHODS FORMING THE SAME

(71) Applicant: Taiwan Semiconductor Manufacturing Co., Ltd., Hsinchu (TW)

(72) Inventors: Yao-Jen Chang, Hsinchu (TW); Chung-Yu Lu, Hsinchu (TW); Ping-Kang Huang, Chiayi City (TW); Sao-Ling Chiu, Hsinchu (TW); Hsien-Pin Hu, Zhubei City (TW); Hao-Yi Tsai, Hsinchu (TW); Shang-Yun Hou, Jubei City (TW)

(21) Appl. No.: 18/606,495

(22) Filed: Mar. 15, 2024

Related U.S. Application Data
(60) Provisional application No. 63/613,155, filed on Dec. 21, 2023.

(51) Int. Cl. H01L 23/48; H01L 21/48; H01L 23/00; H01L 23/31; H01L 25/00; H01L 25/18

(52) U.S. Cl. CPC H01L 23/481; H01L 21/4853; H01L 23/3128; H01L 24/16; H01L 24/32; H01L 24/73; H01L 24/94; H01L 25/18; H01L 25/50; H01L 2224/16225; H01L 2224/32225; H01L 2224/73204; H01L 2224/94; H01L 2924/1431; H01L 2924/181

(57) ABSTRACT

A method includes forming a die, which includes forming a first metal pillar on a first side of a first semiconductor substrate of the die, polishing the first semiconductor substrate of the die to reveal a first through-via in the first semiconductor substrate, and forming a second metal pillar on a second side of the die. The first side and the second side are on opposite sides of the first semiconductor substrate. The method further includes encapsulating the die in an encapsulant, forming a first conductive feature on the first side of the first semiconductor substrate and electrically connecting to the first metal pillar, and forming a second conductive feature on the second side of the first semiconductor substrate and electrically connecting to the second metal pillar.

### PRIORITY CLAIM AND CROSS-REFERENCE

This application claims the benefit of the following provisionally filed U.S. Patent application: Application No. 63/613,155, filed on Dec. 21, 2023, and entitled “DOUBLE SIDE METAL VIA IN LSI DIE FOR DIFFERENT INTERCONNECT PROTOCOL,” which application is hereby incorporated herein by reference.

### BACKGROUND

With the evolving of integrated circuits, increasingly more functions are building into integrated circuit packages. Accordingly, the requirement of local communication and interconnection between neighboring device dies and packages also becomes more demanding.

Accordingly, local interconnect dies are used as part of the package.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-13 and 14A illustrate the cross-sectional views of intermediate stages in the formation of a package in accordance with some embodiments.

FIGS. 14B and 14C illustrate some packages in accordance with some embodiments.

FIG. 15 illustrates a top view of a package in accordance with some embodiments.

FIGS. 16A and 16B illustrate a local interconnect dies in accordance with some embodiments.

FIG. 17 illustrates a process flow for forming a package in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A package including Local Silicon Interconnect (LSI) dies (also referred to as bridge dies) and the method of forming the same are provided. In accordance with some embodiments of the present disclosure, a plurality of LSI dies, which have different thicknesses, are formed. The LSI dies include through-vias, and metal pillars (sometimes referred to as metal vias) are formed on the opposite sides of the LSI dies. With the formation of the metal pillars on both sides of the LSI dies, the differences between the thicknesses of the LSI dies may be compensated for. The cracks caused by the TSVs on the backside of the LSI dies may be reduced. The process risk of trapping bubbles during thermal processes is also reduced.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

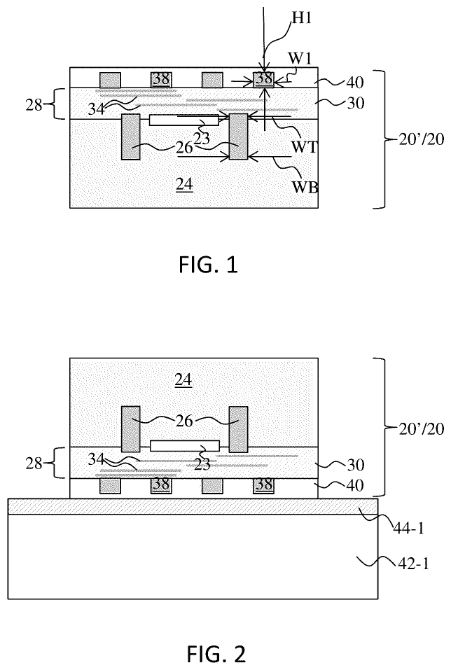

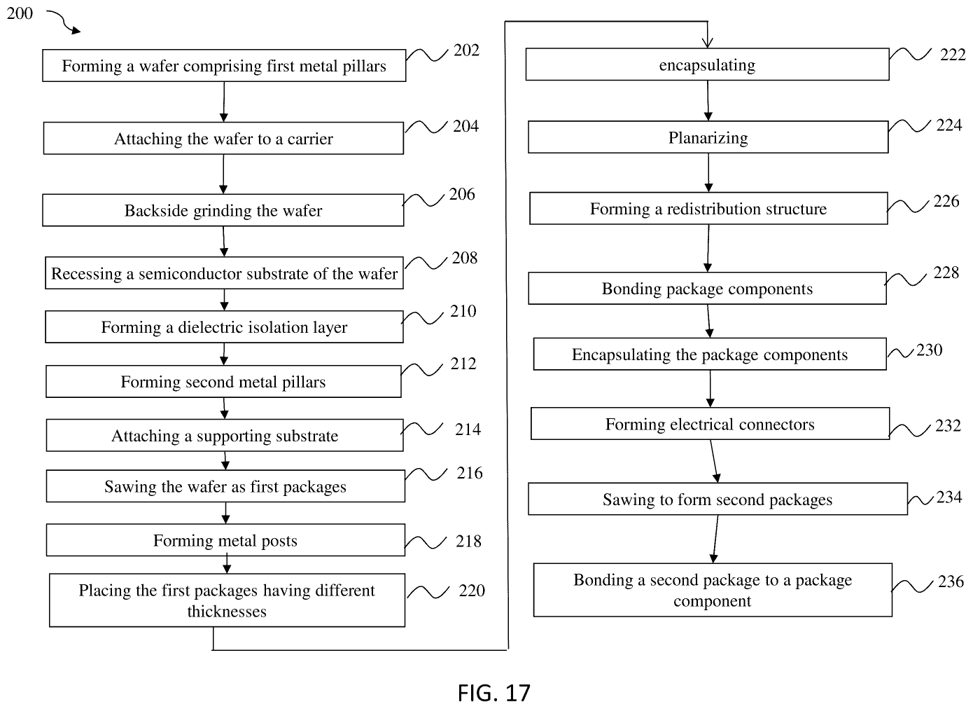

FIGS. 1-13 and 14A illustrate the cross-sectional views of intermediate stages in the formation of a package in accordance with some embodiments of the present disclosure. The corresponding processes are also reflected schematically in the process flow shown in FIG. 17.

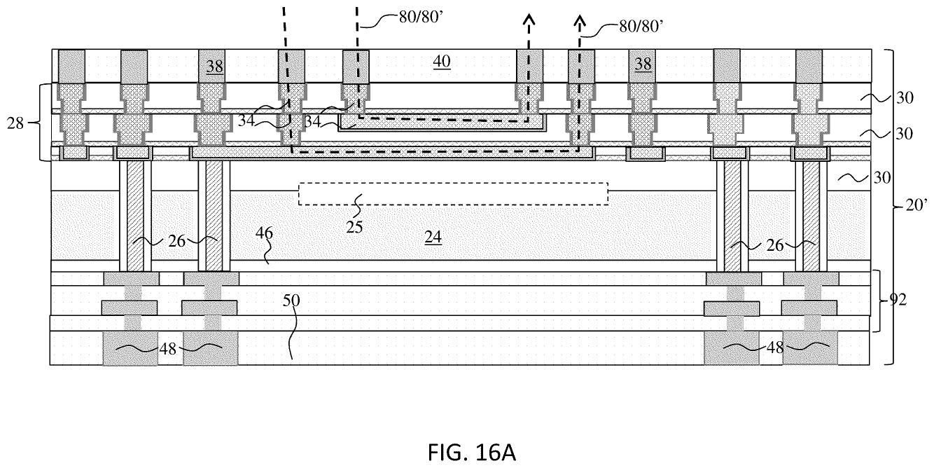

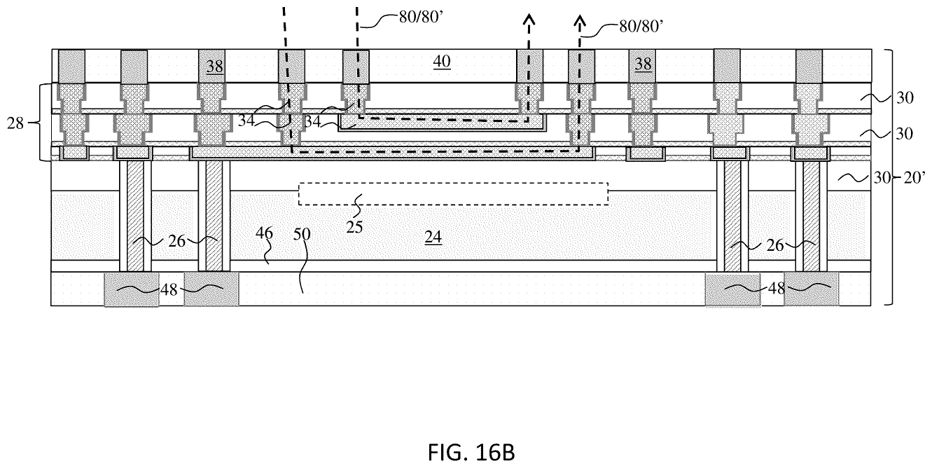

FIGS. 1 through 5 illustrate the views in the formation of an LSI die with double-side metal pillars in accordance with some embodiments. FIG. 1 illustrates a cross-sectional view in the formation of a wafer 20, which includes a plurality of identical dies 20′ therein, with one of the dies 20′ being illustrated. The respective process is illustrated as process 202 in the process flow 200 as shown in FIG. 17. In accordance with some embodiments, die 20′ is an LSI die formed based on a silicon substrate, and includes a plurality of electrical paths for electrically interconnecting two package components. Some details of die 20′ are discussed referring to FIG. 16A, which illustrates an amplified view of an example die 20′.

As shown in FIG. 1, in accordance with some embodiments, die 20′ includes semiconductor substrate 24 and the features formed at a top surface of semiconductor substrate 24. Semiconductor substrate 24 may be formed of or comprise crystalline silicon, crystalline germanium, crystalline silicon germanium, carbon-doped silicon, or the like. Semiconductor substrate 24 may also be a bulk semiconductor substrate or a Semiconductor-On-Insulator (SOI) substrate.

In accordance with some embodiments, die 20′ does not include active devices and passive devices. In accordance with alternative embodiments, die 20′ includes integrated circuit devices 25 (also refer to FIGS. 16A), which are formed at a surface of semiconductor substrate 24. Accordingly, integrated circuit devices 25 are shown as being dashed to represent that they may be or may not be formed. Integrated circuit devices 25 (if formed) may include Complementary Metal-Oxide Semiconductor (CMOS) transistors, resistors, capacitors, diodes, and/or the like in accordance with some embodiments.

Referring back to FIG. 1 (and also referring to FIG. 16A), die 20′ may include through-vias 26 (also referred to as through-silicon vias (TSVs) or through-semiconductor vias (also TSVs)) extending to an intermediate level of semiconductor substrate 24, wherein the intermediate level is between the top surface and the bottom surface of semiconductor substrate 24. In accordance with some embodiments, through-vias 26 have top widths WT and bottom widths TB smaller than top width WB.

Interconnect structure 28 is formed over semiconductor substrate 24. In accordance with some embodiments, interconnect structure 28 includes a plurality of dielectric layers 30, and a plurality of conductive features 34 in the dielectric layers 30. The dielectric layers 30 may include an Inter-Layer Dielectric (ILD) (not shown separately) that fills the spaces between the gate stacks of transistors in integrated circuit devices 25 (if formed). In accordance with some embodiments, the ILD is formed of silicon oxide, silicon nitride, silicon oxynitride, Phospho Silicate Glass (PSG), Boro Silicate Glass (BSG), Boron-doped Phospho Silicate Glass (BPSG), Fluorine-doped Silicate Glass (FSG), or the like. The ILD may be formed using spin-on coating, Flowable Chemical Vapor Deposition (FCVD), Chemical Vapor Deposition (CVD), or the like.

The conductive features 34 may include metal lines and vias, which may form conductive paths acting as bridges interconnecting two package components, and are connected to through-vias 26. Although the vias are not shown in FIG. 1, the vias are also formed, and are shown in the details shown in FIG. 16. If integrated circuit devices 25 are formed, the conductive features 34 may also be connected to the integrated circuit devices 25 (if formed). The metal lines at a same level are collectively referred to as a metal layer hereinafter. In accordance with some embodiments, interconnect structure 28 includes a plurality of metal layers interconnected through the vias. The metal lines and vias may be formed of copper, a copper alloy, and/or another metal.

In accordance with some embodiments, electrical connectors 38 are formed at the top surface of wafer 20. Electrical connectors 38 may include metal pillars, which may be formed through plating, and have vertical and straight sidewalls. Accordingly, throughout the description, electrical connectors 38 are referred to as metal pillars 38. There may be, or may not be, solder layers on top of metal pillars 38.

In accordance with some embodiments, the height H1 of metal pillars 38 are determined based on the structure of the package the corresponding die 20′ is to be incorporated, and possibly based on the width W1 of the metal pillars 38. The determination of height H1 is discussed in subsequent paragraphs.

In accordance with some embodiments, dielectric layer 40 is formed to cover and embed metal pillars 38 therein. Dielectric layer 40 may be formed of or comprise a polymer, which may comprise polyimide, polybenzoxazole (PBO), benzocyclobutene (BCB), or the like. In accordance with alternative embodiments, dielectric layer 40 is not formed.

FIG. 2 illustrates the placement of wafer 20 onto release film 44-1, which is further on carrier 42-1. The respective process is illustrated as process 204 in the process flow 200 as shown in FIG. 17. Carrier 42-1 may be a glass carrier, a silicon wafer, an organic carrier, or the like. Release film 44-1 may be formed of a polymer-based material and/or an epoxy-based thermal-release material (such as a Light-To-Heat-Conversion (LTHC) material). Release film 44-1 is capable of being decomposed under radiation such as a laser beam, so that carrier 42-1 may be de-bonded from the overlying structures that will be formed in subsequent processes. In accordance with some embodiments of the present disclosure, release film 44-1 is applied on carrier 44-2 through coating.

A backside grinding process is then performed to thin wafer 20. The respective process is illustrated as process 206 in the process flow 200 as shown in FIG. 17. In accordance with some embodiments, the backside grinding process is performed until TSVs 26 are revealed. The backside grinding process may be performed through a Chemical Mechanical Polish (CMP) process or a mechanical grinding process.

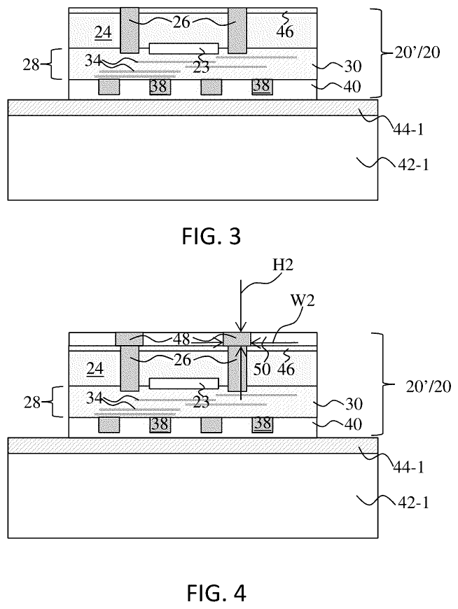

Next, referring to FIG. 3, the semiconductor substrate 24 in device dies 20′ may be recessed in an etching process, so that the top portions of TSVs 26 protrude over semiconductor substrate 24. The respective process is illustrated as process 208 in the process flow 200 as shown in FIG. 17. Dielectric isolation layer 46 may then be formed to encircle the top portions of TSVs 26. The respective process is illustrated as process 210 in the process flow 200 as shown in FIG. 17. The formation of dielectric isolation layer 46 may include a deposition process to deposit a dielectric layer onto semiconductor substrate 24, so that the protruding portions of TSVs 26 are in the dielectric layer, followed by a planarization process. The portions of the dielectric layer over TSVs 26 are removed, and the remaining portions of the dielectric layer form the dielectric isolation layer 46, which becomes parts of dies 20′ and wafer 20.

Referring to FIG. 4, electrical connectors 48 are formed. Electrical connectors 48 include metal pillars, which have vertical and straight sidewalls. The respective process is illustrated as process 212 in the process flow 200 as shown in FIG. 17. Electrical connectors 48 may comprise copper, and may or may not include titanium, nickel, palladium, or the like. Electrical connectors 48 are referred to as metal pillars 48 hereinafter. In accordance with some embodiments, metal pillars 48 are formed by forming a metal seed layer (such as a titanium layer and a copper layer over the titanium layer), forming a plating mask such as a patterned photoresist, plating metal pillars 48 in the plating mask, removing the plating mask, and etching the portions of the metal seed layer previously covered by the plating mask.

In accordance with some embodiments, the height H2 of metal pillars 48 are selected based on the structure of the package the corresponding die 20′ is to be incorporated, and possibly based on the width W2 of the metal pillars 48. The determination of height H2 is discussed in subsequent paragraphs.

Further referring to FIG. 4, dielectric layer 50 is formed on metal pillars 48. In accordance with some embodiments, dielectric layer 50 comprises a molding compound, a molding underfill or the like. The molding compound or molding underfill may include a base dielectric material such as a polymer, a resin, an epoxy, and/or the like, and filler particles in the base material. The filler particles may be the dielectric particles of SiO₂, Al₂O₃, silica, or the like, and may have spherical shapes. Also, the spherical filler particles may have a plurality of different diameters.

Alternatively, dielectric layer 50 may be formed of a silicon-containing dielectric material, which silicon-containing dielectric material may be selected from SiO, SiC, SiN, SiON, SiOC, SiCN, SiOCN, or the like, or combinations thereof. The formation process may include a deposition process followed by a planarization process. In accordance with yet alternative embodiments, dielectric layer 50 may be formed of or comprises a homogeneous polymer such as polyimide, PBO, BCB, or the like. Dielectric layer 50 may have its top surface coplanar with or higher than the top surfaces of metal pillars 48.

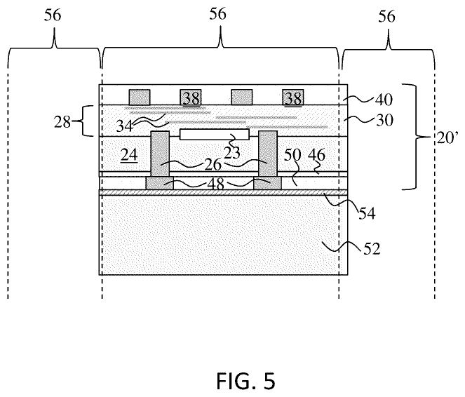

In subsequent processes, a supporting substrate 52 (FIG. 5) may be attached to wafer 20, for example, through adhesive film 54. The respective process is illustrated as process 214 in the process flow 200 as shown in FIG. 17. The supporting substrate 52 may be a silicon substrate in accordance with some embodiments. Layer 54, which may be an adhesive film or a bond layer, may be used to attach supporting substrate 52 to wafer 20. When being a bond layer, layer 54 may comprise a silicon-containing dielectric material such as SiO, SiN, SiCN, SiOCN, or the like.

Next, as also shown in FIG. 5, wafer 20 is sawed in a singulation process, which may be performed using a sawing blade. The respective process is illustrated as process 216 in the process flow 200 as shown in FIG. 17. Wafer 20 is thus separated into packages 56, each including a discrete device die 20′ and a piece of supporting substrate 52.

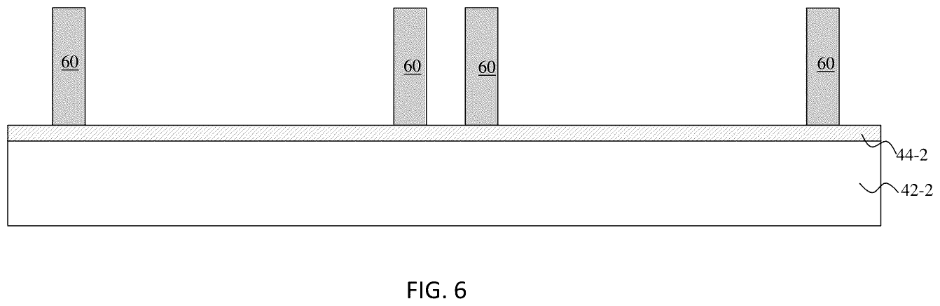

FIGS. 6-13 and 14A illustrate the cross-sectional views in the formation of a package in accordance with some embodiments, in which two or more dies 20′ including double-side metal pillars are adopted.

Referring to FIG. 6, carrier 42-2 is provided, with release film 44-1 being coated on carrier 42-2. Carrier 42-2 may be a glass carrier, a silicon wafer, an organic carrier, or the like. Release film 44-1 may be formed of a polymer-based material and/or an epoxy-based thermal-release material, such as a LTHC coating. There may be a buffer dielectric layer (not shown) such as a PBO layer formed on release film 44-1.

Metal posts 60 are then formed. The respective process is illustrated as process 218 in the process flow 200 as shown in FIG. 17. In accordance with some embodiments, the formation process includes depositing a metal seed layer, forming and patterning a plating mask such as a photoresist, plating a metallic material in the plating mask, removing the plating mask, and removing the portions of the metal seed layer previously covered by the plating mask. The plated metallic material and the remaining portions of the metal seed layer are collectively referred to as metal posts 60.

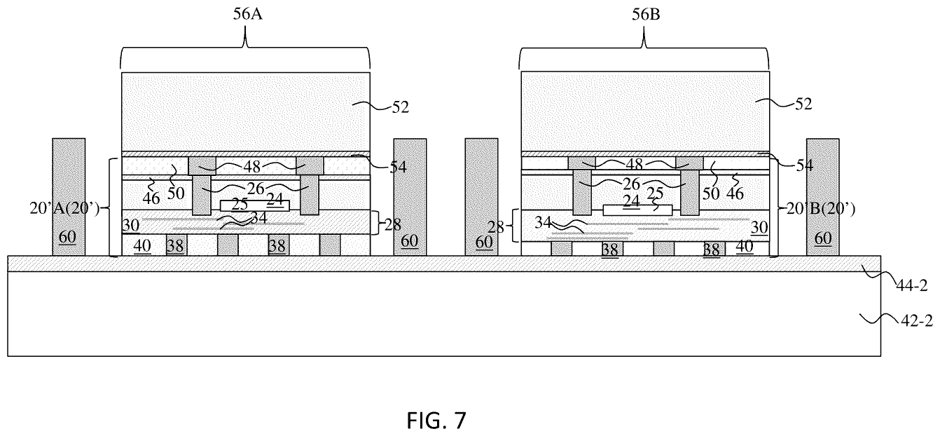

Next as shown in FIG. 7, packages 56 (including packages 56A and 56B), which include dies 20′ (including dies 20′A and 20′B, respectively), are placed over carrier 42-2. The respective process is illustrated as process 220 in the process flow 200 as shown in FIG. 17. The formation process of each of packages 56A and 56B may be found referring to FIGS. 1 through 5. In accordance with some embodiments, the attachment may be performed through a die-attach film (not shown), which may be adhered on wafer 20 (FIG. 5) before wafer 20 is sawed into packages 56. In accordance with some embodiments, packages 56A and 56B have different structures and different thicknesses, which difference in thicknesses is compensated for by metal pillars 38 and 48, as will be discussed in subsequent paragraphs.

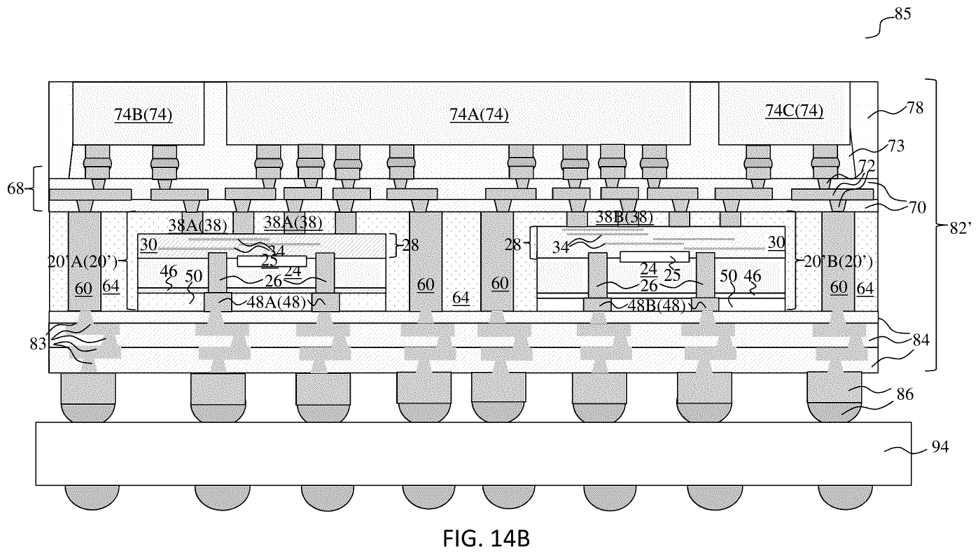

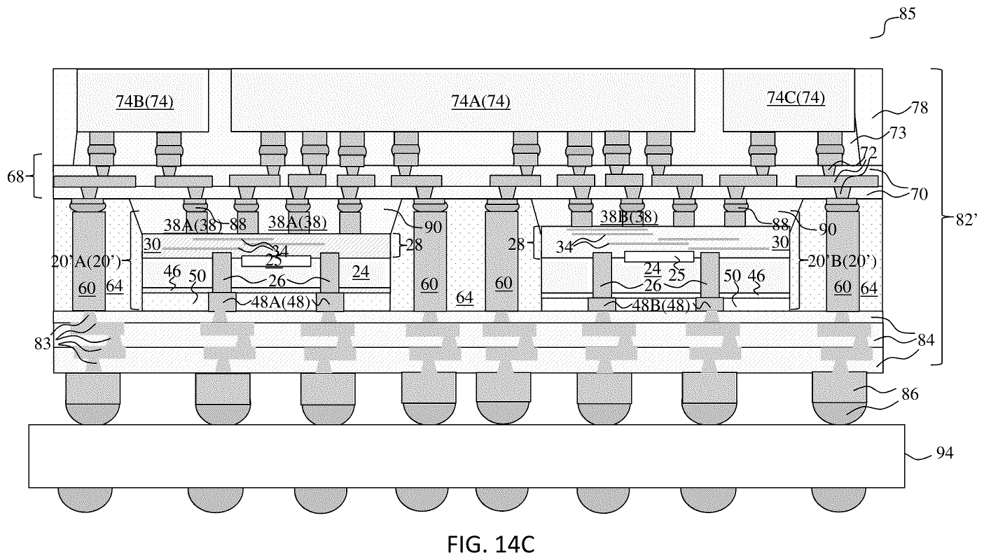

In accordance with some embodiments, the top surfaces of metal pillars 48 in die 20′A is coplanar with or substantially coplanar with (for example, with a variation smaller than 10 percent of the heights of metal pillars 38) the top surfaces of metal pillars 48 in die 20′B after the placement. This may be achieved by selecting the heights of metal pillars 38 and 48 to compensate for the differences of the thicknesses of the interconnect structures 28 and semiconductor substrate 24 in dies 20′A and 20′B, as will be discussed referring to FIG. 14A.

In accordance with some embodiments, a thinning process may be performed to either remove or thin the supporting substrates 52. The thinning process may be performed through a CMP process or a mechanical polish process. The thinning may reduce the aspect ratio of the gaps between packages 56A and 56B and metal posts 60, so that the subsequent gap-filling process is easier.

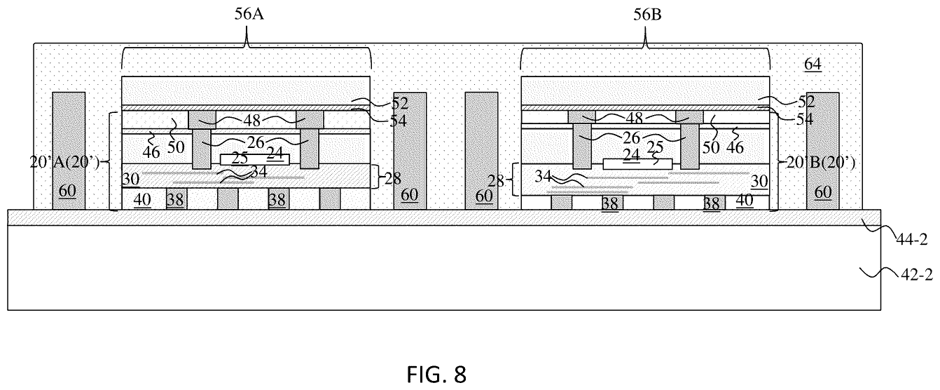

Referring to FIG. 8, packages 56A and 56B and metal posts 60 are encapsulated in encapsulant 64. The respective process is illustrated as process 222 in the process flow 200 as shown in FIG. 17. Encapsulant 64 may include a molding compound, a molding underfill, an epoxy, and/or a resin. The top surface of encapsulant 64 may be higher than the top surfaces of packages 56A and 56B. When formed of molding compound or molding underfill, encapsulant 64 may include a base material, which may be a polymer, a resin, an epoxy, or the like, and filler particles in the base material. The filler particles may be the dielectric particles of SiO₂, Al₂O₃, silica, or the like, and may have spherical shapes. Also, the spherical filler particles may have a plurality of different diameters.

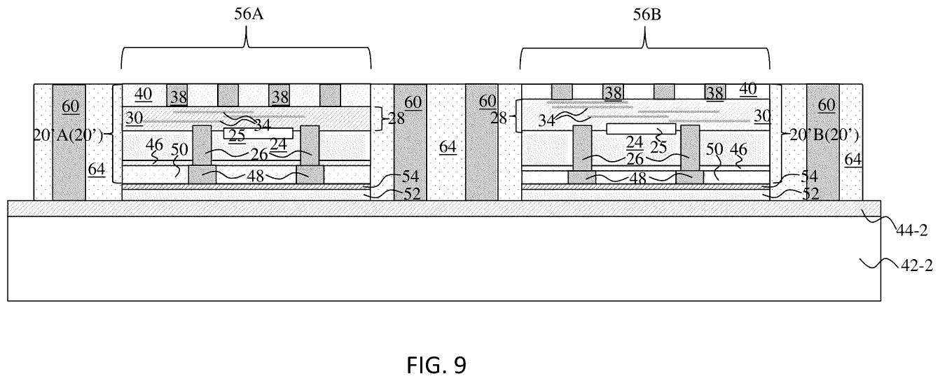

In a subsequent process, as shown in FIG. 9, a planarization process such as a CMP process or a mechanical grinding process is performed to thin encapsulant 64 and packages 56A and 56B. The respective process is illustrated as process 224 in the process flow 200 as shown in FIG. 17. Metal posts 60 are alternatively referred to as through-vias 60 hereinafter since they penetrate through the thinned encapsulant 64. Due to that the top surfaces of metal pillars 38 in die 20′A are coplanar with or substantially coplanar with the top surfaces of metal pillars 38 in die 20′B, after the planarization process, the metal pillars 38 in both of dies 20′A and 20′B are revealed. Through-vias 60 are also revealed.

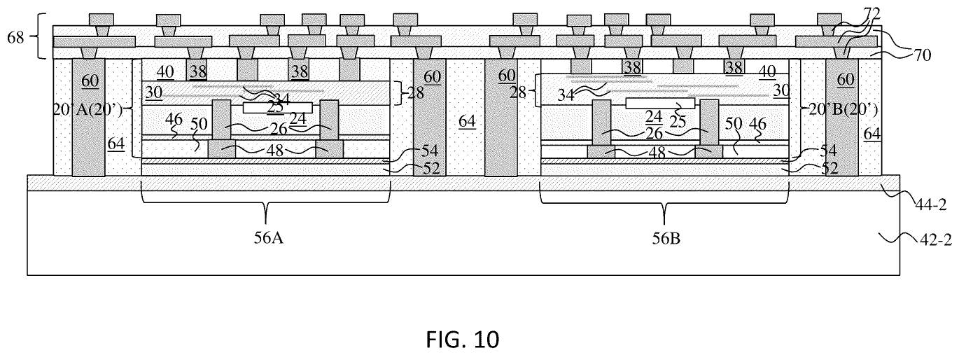

FIG. 10 illustrates the formation of redistribution structure 68, which includes dielectric layers 70 and Redistribution Lines (RDLs) 72 in dielectric layers 70. The respective process is illustrated as process 226 in the process flow 200 as shown in FIG. 17. Redistribution structure 68 may be formed layer-by-layer. For example, the formation of one layer of RDLs 72 may include forming a dielectric layer 70, and forming openings in the dielectric layer 70 through a patterning process. A metal seed layer (not shown) is then deposited, which includes some portions over, and some other portions extending into dielectric layer 70. Dielectric layers 70 may be formed of or comprise an organic material such as PBO, polyimide, BCB, or the like, or inorganic materials such as silicon oxide, silicon nitride, or the like. A patterned mask (not shown) such as a photoresist is then formed over the metal seed layer, followed by a metal plating process to deposit a metallic material on the exposed metal seed layer. The patterned mask and the portions of the metal seed layer covered by the patterned mask are then removed, leaving a layer of RDLs 72.

In accordance with some embodiments, the metal seed layer includes a titanium layer and a copper layer over the titanium layer. The metal seed layer may be formed using, for example, Physical Vapor Deposition (PVD) or a like process. The plated material may include copper, aluminum, cobalt, nickel, gold, silver, tungsten, or alloys thereof. The plating may be performed through, for example, an electrochemical plating process. The dielectric layers 70 and RDLs 72 are formed layer-by-layer to collectively form redistribution structure 68.

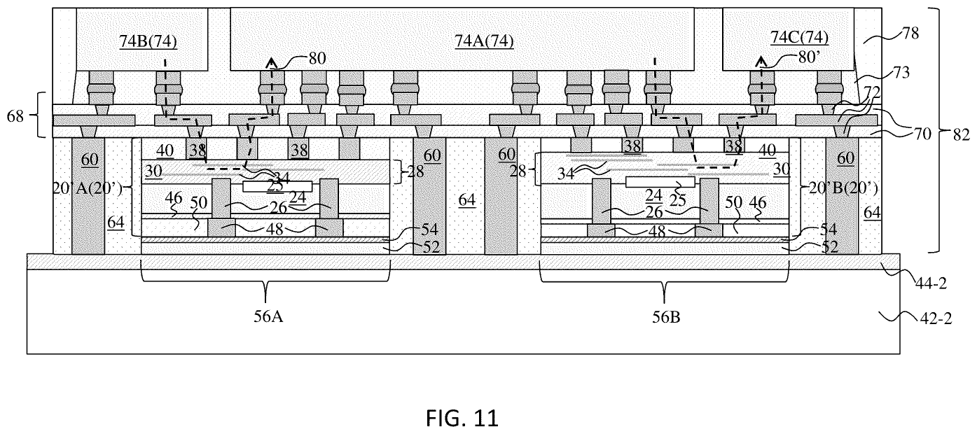

FIG. 11 illustrates the bonding of package components 74 (including package components 74A, 74B, and 74C, for example) to redistribution structure 68 in accordance with some embodiments. The respective process is illustrated as process 228 in the process flow 200 as shown in FIG. 17. Package components 74 may include device dies, multi-die stacks, packages, or the like. In accordance with some embodiments, package components 74A are system dies including a plurality of device dies packaged as a system. For example, the device dies in package components 74A may include logic dies and memory dies. Package components 74B and 74C may be discrete device dies or may be packages including systems, memory stacks (with memory dies bonded to form a stack), or combinations thereof. The memory stacks may include High bandwidth memory (HBM) stacks.

In accordance with some embodiments, dies 20′A and 20′B are LSI dies. For example, die 20′A may electrically interconnect package components 74A and 74B through electrical paths 80, and die 20′B may electrically interconnect package components 74A and 74C through electrical paths 80′.

FIG. 16A illustrates the details of die 20′, which may be die 20′A and/or 20′B in accordance with some embodiments. The illustrated die 20′ is an LSI die. In accordance with some embodiments of the present disclosure, die 20′ includes substrate 24. Interconnect structure 28 is formed over substrate 24, and includes dielectric layers 30 (which may include low-k dielectric layers and etch stop layers), and metal lines and vias 34 in dielectric layers 30.

Dielectric layers 30 may include IMD layers. In accordance with some embodiments of the present disclosure, some lower ones of dielectric layers 30 are formed of low-k dielectric materials having dielectric constants (k-values) lower than 3.8, and the k values may be lower than about 3.0. Dielectric layers 30 may be formed of a carbon-containing low-k dielectric material, Hydrogen SilsesQuioxane (HSQ), MethylSilsesQuioxane (MSQ), or the like. Metal lines and vias 34 may be formed using single damascene and/or dual damascene processes.

Dielectric layers 30 may further include a passivation layer(s) over the dielectric layers 30 that have low k values. The passivation layer has the function of isolating the underlying low-k dielectric layers (if any) from the adverse effect of detrimental chemicals and moisture. The passivation layer may be formed of or comprise non-low-k dielectric materials such as silicon oxide, silicon nitride, USG, or the like, or composite layers thereof. Metal pillars 38 and dielectric layer 40 are formed at the surface of die 20′.

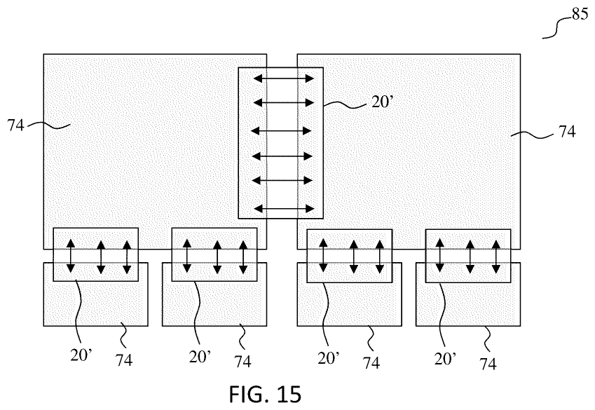

In accordance with some embodiments, die 20′ may be a bridge die, which is used for electrically and signally interconnecting package components 74 (FIGS. 14A, 14B, 14C, and 15). Metal lines and vias 34 and metal pillars 38 may collectively form a plurality of conductive paths (bridges) 80 or 80′, each including two of the metal pillars 38 and the corresponding metal lines/pads and vias 34.

In accordance with some embodiments of the present disclosure, die 20′ further includes TSVs 26 and metal pillars 48. TSVs 26 may be formed of or comprise Cu, Al, W, or the like, or alloys thereof. Die 20′ thus is a dual-sided device, which has conductive features on both of the top side and the bottom side. The conductive features 38 and 48 are electrically interconnected through through-vias 26. The electrical paths 80/80′ may also be electrically connected to through-vias 26 and metal pillars 38 and 48 in accordance with some embodiments.

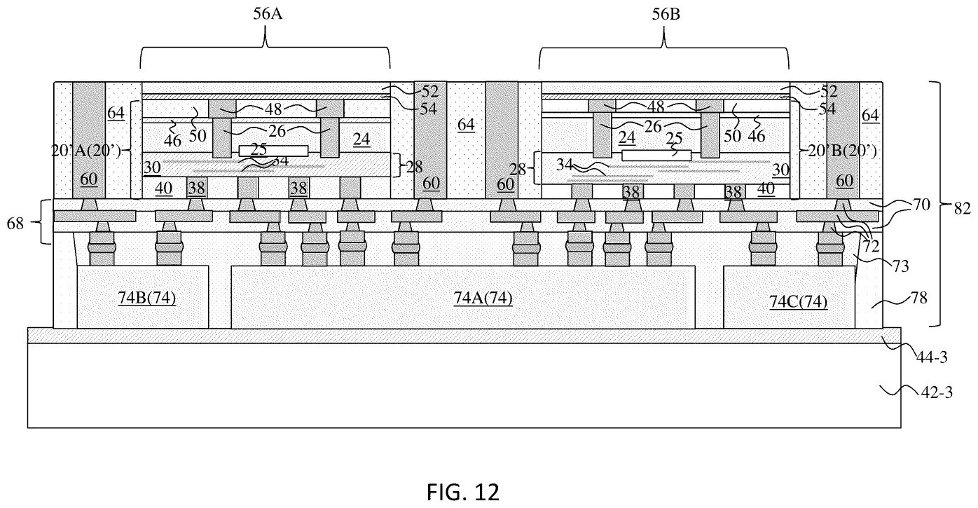

Further referring to FIG. 11, encapsulant 78 is dispensed, cured, and planarized. The respective process is illustrated as process 230 in the process flow 200 as shown in FIG. 17. The structure over release film 44-2 is referred to as reconstructed wafer 82 hereinafter. Next, a carrier switch process is performed, and reconstructed wafer 82 is attached to carrier 42-3 (FIG. 12), for example, through release film 44-3. After the carrier switch process, reconstructed wafer 82 is de-bonded from carrier 42-2. As a result, encapsulant 64 and through-vias 60 may be revealed. Supporting substrate 52, if remaining, may be exposed. The resulting structure is shown in FIG. 12.

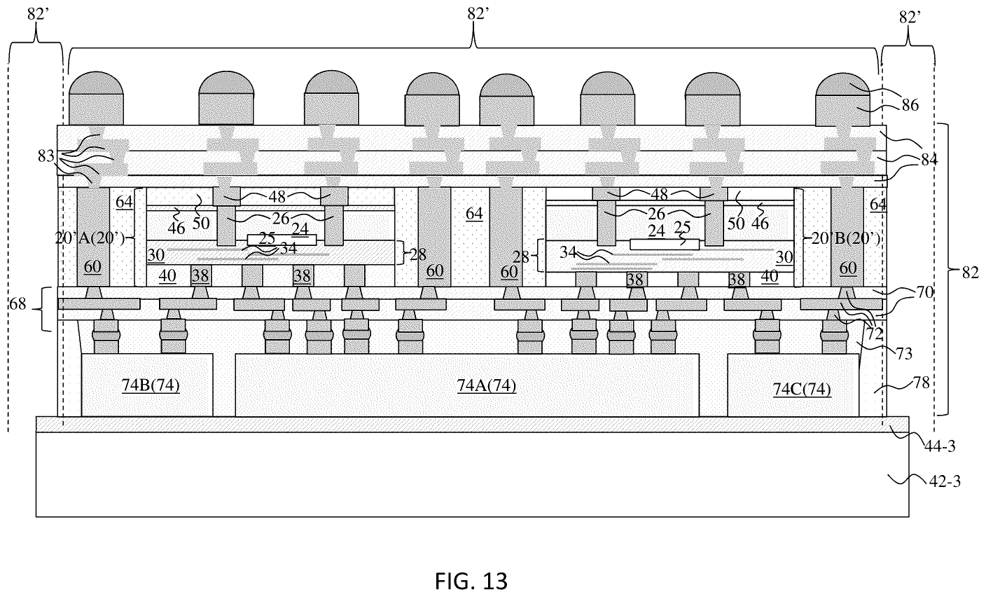

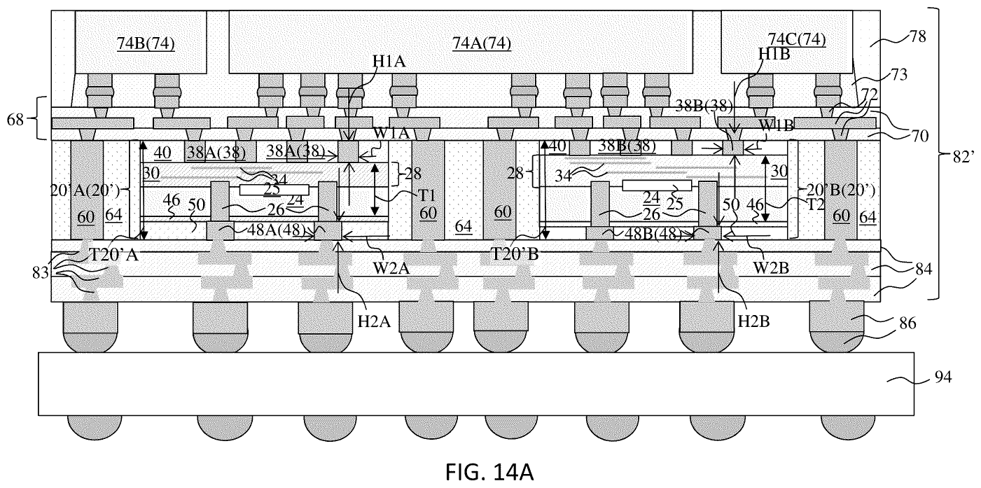

FIG. 13 further illustrates the formation of RDLs and electrical connectors on reconstructed wafer 82 in accordance with some embodiments. The respective process is illustrated as process 232 in the process flow 200 as shown in FIG. 17. In accordance with some embodiments, a planarization process may be performed to remove supporting substrates 52 and layers 54, and to level the top surfaces of metal pillars 48 with the top surfaces of through-vias 60. Next, dielectric layer 84 is formed. In accordance with some embodiments, dielectric layer 84 comprises polyimide, PBO, BCB, or the like. Alternatively, dielectric layer 84 may be formed of an inorganic dielectric material such as silicon oxide, silicon nitride, or the like. More dielectric layers 84 and RDLs 83 are then formed.

Electrical connectors 86 are then formed on the surface of reconstructed wafer 82. In accordance with some embodiments, electrical connectors 86 include metal pillars, solder layers, and/or the like. The formation process may include patterning dielectric layer 84 to reveal metal pillars 48 and through-vias 60, forming a plating mask such as a patterned photoresist, plating electrical connectors 86 in the plating mask, removing the plating mask, and etching the portions of the metal seed layer previously covered by the plating mask. When solder layers are plated, a reflow process may be performed.

In a subsequent process, reconstructed wafer 82 may be de-bonded from carrier 42-3, and is placed on a dicing tape (not shown). Reconstructed wafer 82 is then singulated to form a plurality of packages 82′. The respective process is illustrated as process 234 in the process flow 200 as shown in FIG. 17.

In a subsequent process, as shown in FIG. 14A, package 82′ may be bonded to package component 94, which may be a package substrate, a printed circuit board, an interposer, another package, or the like. The respective process is illustrated as process 236 in the process flow 200 as shown in FIG. 17. Package 85 is thus formed.

As shown in FIG. 14A, the portions of dies 20′A and 20′B excluding metal pillars 38 and 48 may have thicknesses different from each other. For example, assuming die 20′B is the LSI die for interconnecting two system packages that include logic dies therein, and die 20′A is the LSI die for interconnecting a system package and a memory package, die 20′A may have fewer routing layers, and may be thinner, than die 20′B. Accordingly, the thickness T1 is smaller than thickness T2, wherein thicknesses T1 and T2 are the thicknesses of dies 20′A and 20B′ excluding the thickness of metal pillars 38 and 48. In accordance with some embodiments, the thicknesses of semiconductor substrates 24 in dies 20′A and 20′B may have the same thickness, and hence the thickness difference (T2−T1) may be equal to the difference of the thicknesses of interconnect structures 28 of dies 20′A and 20′B.

In the following discussion, the metal pillars 38 in die 20′A are referred to as metal pillars 38A, and the metal pillars 38 in die 20′B are referred to as metal pillars 38B. The metal pillars 48 in die 20′A are referred to as metal pillars 48A, and the metal pillars 48 in die 20′B are referred to as metal pillars 48B. The thicknesses of metal pillars 38A and 38B are denoted as H1A and H1B, respectively. The thicknesses of metal pillars 48A and 48B are denoted as H2A and H2B, respectively.

As shown in FIG. 14A, the thickness T20′A of die 20′A is equal to the thickness T20′B of die 20′B. On the other hand, thickness T1 of die 20′A is smaller than thickness T2 of die 20′B, wherein the thicknesses T1 and T2 are the thicknesses of dies 20′A and 20′B, respectively, excluding the thicknesses of metal pillars 38 and 48. In accordance with some embodiments, the thicknesses of metal pillars 38 of dies 20′A and 20′B are designed according to the relationship (H1A+H2A)−(H1B+H2B)=(T2-T1). Due to the process variations, for example, the variation caused by the non-planarity in the CMP process, in the structure shown in FIG. 14A (and FIGS. 14B and 14C), the value of ((H1A+H2A)−(H1B+H2B)) may be designed to be α*(T2-T1), wherein process variation factor α may be between 0.9 and 1.1.

Accordingly, the design of dies 20A′ and 20B′ involves determining thicknesses T1 and T2, and then calculating thicknesses H1A, H2A, H1B, and H2B. Thicknesses T1 and T2 may be determined by estimating the thicknesses of interconnect structures 28 and the semiconductor substrates 24 of dies 20′A and 20′B. Alternatively, thicknesses T1 and T2 may be determined by manufacturing sample dies 20′A and 20′B, and then measuring the thicknesses T1 and T2 from sample dies 20′A and 20′B.

It is appreciated that the reliability in the formation of metal pillars 38 and 48 is related to the aspect ratios of metal pillars 38 and 48. A high aspect ratio may cause problems in the manufacturing of metal pillars 38 and 48, especially of die 20′A, whose metal pillar heights H1A and H2A are greater than the heights H1B and H2B of die 20′B.

Furthermore, reducing the aspect ratio of metal pillars 38 will result in the aspect ratio of metal pillars 48 to be increased, and vice versa. In accordance with some embodiments, metal pillars 38 and 48 of both of dies 20′A and 20′B are such designed, so that the aspect ratio H1A/W1A is equal to H2A/W2A for die 20′A. Also, the aspect ratio H1B/W1B is equal to H2B/W2B for die 20′B. With these relationships, no aspect ratio is excessively high, and the reliability in the manufacturing of metal pillars 38 and 48 is improved.

In accordance with the embodiments, metal pillars are formed on both sides of each of dies 20′A and 20′B. The ability of using the thicknesses of metal pillars to adjust the thickness of dies 20′A and 20′B is thus improved. As a comparison, if metal pillars 48 are not formed, and electrical connectors 86 (or backside RDLs) are formed to directly contact TSVs 26, metal pillars 38 have to take all the responsibility of compensating for the thickness difference (T2-T1). The height H1A and the aspect ratio H1A/W1A of die 20′A may be too high, and may cause reliability issue. Besides, without the buffering of metal pillars 48, the direct connection of the electrical connectors 86 to TSVs 26 may cause TSV crack issues.

In accordance with some embodiments, in case the thickness difference (T2-T1) is too big and is difficult to be compensated for by metal pads 38 and 48, die 20′A may adopt the structure shown in FIG. 16B. Die 20′B, on the other hand, may adopt the structure shown in FIG. 16A. As shown in FIG. 16B, an interconnect structure 92 may be formed between through-vias 26 and metal pads 48. The thickness of die 20′A thus may be increased without requiring metal pads 38A and 38B to be too high. The formation of the interconnect structure 92 may be essentially the same as that for forming redistribution structure 68. The interconnect structure 92 in die 20′A may not have any lateral routing metal line, and is solely for vertical connections. Accordingly, the vias and the metal pads in the interconnect structure are vertically aligned, with the metal pads being slightly wider than the respective overlying and underlying vias.

In the embodiments as shown in FIG. 14A, dielectric layers 40 are formed to encapsulate metal pillars 38. Accordingly, on one side of one of dies 20′A and 20′B, a polymer dielectric layer 40 (formed of polyimide, PBO, BCB, or the like) contacts and encircles metal pillars 38. On the other side, dielectric layer 50 contacts and encircles metal pillars 48. Dielectric layer 50 may be formed of a polymer such as polyimide, PBO, BCB, or the like. Alternatively, dielectric layer 50 may be formed of molding compound, molding underfill, an inorganic dielectric material such as SiO, SiN, or the like.

FIG. 14B illustrates the package 85 formed in accordance with alternative embodiments. These embodiments are similar to the embodiments in FIG. 14A, except that the dielectric layer 40 in one or both of dies 20′A and 20′B is not formed. Accordingly, encapsulant 64 fills the spaces between, and encircles, metal pillars 38.

FIG. 14C illustrates the package 85 formed in accordance with alternative embodiments. These embodiments are similar to the embodiments in FIG. 14A, except that instead of forming dielectric layer 40 and RDLs starting directly from the metal pillars 38 and through-vias 60, solder bonding is adopted. Accordingly, metal pillars 38 and through-vias 60 are bonded to the overlying RDLs 72 through solder regions 88. Underfill 90 may be dispensed to encapsulate metal pillars 38 and solder regions 88 therein.

FIG. 15 illustrates a top view of a package 85 in accordance with some embodiments, which includes a plurality of package components 74. Dies 20′, which include LSI dies, are located underlying (FIGS. 14A, 14B, and 14C) package components 74. Each of LSI dies 20′ may electrically interconnect two (or more) neighboring package components 74. Due to the differences between package components, dies 20′ may have different structures, and metal pillars 38 and 48 are formed to compensate for the differences of their thicknesses.

In above-illustrated embodiments, some processes and features are discussed in accordance with some embodiments of the present disclosure to form a three-dimensional (3D) package. Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The embodiments of the present disclosure have some advantageous features. By forming metal pillars on both sides of the dies that have TSVs, it is easy to compensate for some high thickness differences between the dies. The TSV cracking problem is reduced.

In accordance with some embodiments of the present disclosure, a method comprises forming a first die comprising forming a first metal pillar on a first side of a first semiconductor substrate of the first die; polishing the first semiconductor substrate of the first die to reveal a first through-via in the first semiconductor substrate; and forming a second metal pillar on a second side of the first die, wherein the first side and the second side are on opposite sides of the first semiconductor substrate; encapsulating the first die in an encapsulant; forming a first conductive feature on the first side of the first semiconductor substrate and electrically connecting to the first metal pillar; and forming a second conductive feature on the second side of the first semiconductor substrate and electrically connecting to the second metal pillar.

In an embodiment, the method further comprises forming a second die comprising forming a third metal pillar on a first side of a second semiconductor substrate of the second die, wherein the third metal pillar and the first metal pillar have different heights; forming a fourth metal pillar on a second side of the second die; and encapsulating the second die in the encapsulant.

In an embodiment, the method further comprises determining a first thickness of a first portion of the first die, wherein the first portion comprises a first interconnect structure of the first die; determining a second thickness of a second portion of the second die, wherein the second portion comprises a second interconnect structure of the second die; determining first heights of the first metal pillar and the second metal pillar; and determining second heights of the third metal pillar and the fourth metal pillar, so that a first sum of the first thickness and the first heights is equal to a second sum of the second thickness and the second heights.

In an embodiment, the method further comprises bonding a first package component and a second package component over the first die, wherein the first die electrically connects the first package component to the second package component. In an embodiment, the forming the second metal pillar comprises a plating process. In an embodiment, the first metal pillar and the second metal pillar have a same aspect ratio. In an embodiment, the first metal pillar is in a polymer layer at a time the first die is encapsulated in the encapsulant, and wherein the polymer layer is formed of a homogeneous dielectric material.

In an embodiment, the second metal pillar is in a molding compound comprising a base material and filler particles in the base material. In an embodiment, the encapsulant is filled into spaces between the first metal pillar and an additional first metal pillar of the first die. In an embodiment, the method further comprises, before the first die is encapsulated in the encapsulant, attaching a supporting substrate to the first die.

In an embodiment, the method further comprises, before the first die is encapsulated in the encapsulant, thinning the supporting substrate. In an embodiment, the method further comprises, after the first die is encapsulated in the encapsulant, performing a planarization process to remove the supporting substrate.

In accordance with some embodiments of the present disclosure, a structure comprises a first local interconnect die comprising a first semiconductor substrate; a first through-via penetrating through the first semiconductor substrate; and a first metal pillar and a second metal pillar at opposite surfaces of the first local interconnect die, wherein at least one of the first metal pillar and the second metal pillar is electrically connected to the first through-via; an encapsulant, wherein the first local interconnect die is in the encapsulant; a first dielectric layer contacting a first surface of the first local interconnect die; a first conductive feature in the first dielectric layer and contacting the first metal pillar; a second dielectric layer contacting a second surface of the first local interconnect die, wherein the second surface is opposite to the first surface; and a second conductive feature in the second dielectric layer and contacting the second metal pillar.

In an embodiment, the structure further comprises a second local interconnect die comprising a second semiconductor substrate; a second through-via penetrating through the second semiconductor substrate; and a third metal pillar and a fourth metal pillar at opposite surfaces of the second local interconnect die, wherein the first metal pillar and the second metal pillar have a first total thickness, and the third metal pillar and the fourth metal pillar have a second total thickness different from the first total thickness.

In an embodiment, the first metal pillar and the second metal pillar have a same aspect ratio. In an embodiment, the first local interconnect die is free from active devices therein. In an embodiment, the first metal pillar and the second metal pillar are copper pillars have vertical sidewalls.

In accordance with some embodiments of the present disclosure, a structure comprises a first die comprising a first metal pillar at a first surface of the first die; a second metal pillar at a second surface of the first die, wherein the second surface is opposite to the first surface, and the second metal pillar is electrically connected to the first metal pillar, and wherein the first metal pillar and the second metal pillar have a first total thickness; and a second die comprising a third metal pillar at a third surface of the second die; a fourth metal pillar at a fourth surface of the second die, wherein the fourth surface is opposite to the third surface, and the fourth metal pillar is electrically connected to the third metal pillar, and wherein the third metal pillar and the fourth metal pillar have a second total thickness different from the first total thickness; and an encapsulant comprising a first additional surface coplanar with the first surface of the first die and the third surface of the second die; and a second additional surface coplanar with the second surface of the first die and the fourth surface of the second die.

In an embodiment, the structure further comprises a first package component and a second package component on a same side of the encapsulant and electrically interconnected through the first die; and a third package component and a fourth package component on the same side of the encapsulant and electrically interconnected through the second die.

In an embodiment, the first die comprises a first semiconductor substrate and a first through-via comprising at least a portion in the first semiconductor substrate, wherein the first through-via electrically connects the first metal pillar to the second metal pillar; and the second die comprises a second semiconductor substrate and a second through-via comprising at least a portion in the second semiconductor substrate, wherein the second through-via electrically connects the third metal pillar to the fourth metal pillar.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first die comprising:
forming a first metal pillar on a first side of a first semiconductor substrate of the first die;
polishing the first semiconductor substrate of the first die to reveal a first through-via in the first semiconductor substrate; and
forming a second metal pillar on a second side of the first die, wherein the first side and the second side are on opposite sides of the first semiconductor substrate;
encapsulating the first die in an encapsulant;
forming a first conductive feature on the first side of the first semiconductor substrate and electrically connecting to the first metal pillar; and
forming a second conductive feature on the second side of the first semiconductor substrate and electrically connecting to the second metal pillar.

2. The method of claim 1 further comprising forming a second die comprising:
forming a third metal pillar on a first side of a second semiconductor substrate of the second die, wherein the third metal pillar and the first metal pillar have different heights;
forming a fourth metal pillar on a second side of the second die; and
encapsulating the second die in the encapsulant.

3. The method of claim 2 further comprising:
determining a first thickness of a first portion of the first die, wherein the first portion comprises a first interconnect structure of the first die;
determining a second thickness of a second portion of the second die, wherein the second portion comprises a second interconnect structure of the second die;
determining first heights of the first metal pillar and the second metal pillar; and
determining second heights of the third metal pillar and the fourth metal pillar, so that a first sum of the first thickness and the first heights is equal to a second sum of the second thickness and the second heights.

4. The method of claim 1 further comprising bonding a first package component and a second package component over the first die, wherein the first die electrically connects the first package component to the second package component.

5. The method of claim 1, wherein the forming the second metal pillar comprises a plating process.

6. The method of claim 1, wherein the first metal pillar and the second metal pillar have a same aspect ratio.

7. The method of claim 1, wherein the first metal pillar is in a polymer layer at a time the first die is encapsulated in the encapsulant, and wherein the polymer layer is formed of a homogeneous dielectric material.

8. The method of claim 7, wherein the second metal pillar is in a molding compound comprising a base material and filler particles in the base material.

9. The method of claim 1, wherein the encapsulant is filled into spaces between the first metal pillar and an additional first metal pillar of the first die.

10. The method of claim 1 further comprising, before the first die is encapsulated in the encapsulant, attaching a supporting substrate to the first die.

11. The method of claim 10 further comprising, before the first die is encapsulated in the encapsulant, thinning the supporting substrate.

12. The method of claim 10 further comprising, after the first die is encapsulated in the encapsulant, performing a planarization process to remove the supporting substrate.

13. A structure comprising:
a first interconnect die comprising:
a first semiconductor substrate;
a first through-via in the first semiconductor substrate; and
a first metal pillar and a second metal pillar at opposite surfaces of the first interconnect die, wherein at least one of the first metal pillar and the second metal pillar is electrically connected to the first through-via;
an encapsulant, wherein the first interconnect die is in the encapsulant; and
a metal pillar surrounded by the encapsulant.

14. The structure of claim 13 further comprising a second interconnect die comprising:
a second semiconductor substrate;
a second through-via penetrating through the second semiconductor substrate; and
a third metal pillar and a fourth metal pillar at opposite surfaces of the second interconnect die, wherein the first metal pillar and the second metal pillar have a first total thickness, and the third metal pillar and the fourth metal pillar have a second total thickness different from the first total thickness.

15. The structure of claim 13, wherein the first metal pillar and the second metal pillar have a same aspect ratio.

16. The structure of claim 13 further comprising:
a first dielectric layer contacting a first surface of the first interconnect die;
a first conductive feature in the first dielectric layer and contacting the first metal pillar;
a second dielectric layer contacting a second surface of the first interconnect die, wherein the second surface is opposite to the first surface; and
a second conductive feature in the second dielectric layer and contacting the second metal pillar.

17. A structure comprising:
a first die comprising:
a first metal pillar at a first surface of the first die;
a second metal pillar at a second surface of the first die, wherein the second surface is opposite to the first surface, and the second metal pillar is electrically connected to the first metal pillar, and wherein the first metal pillar and the second metal pillar have a first total thickness; and
a second die comprising:
a third metal pillar at a third surface of the second die; and
a fourth metal pillar at a fourth surface of the second die, wherein the fourth surface is opposite to the third surface, and the fourth metal pillar is electrically connected to the third metal pillar, and wherein the third metal pillar and the fourth metal pillar have a second total thickness different from the first total thickness.

18. The structure of claim 17 further comprising an encapsulant comprising:
a first additional surface coplanar with the first surface of the first die and the third surface of the second die; and
a second additional surface coplanar with the second surface of the first die and the fourth surface of the second die.

19. The structure of claim 18 further comprising:
a first package component and a second package component on a same side of the encapsulant and electrically interconnected through the first die; and
a third package component and a fourth package component on the same side of the encapsulant and electrically interconnected through the second die.

20. The structure of claim 17, wherein:
the first die comprises a first semiconductor substrate and a first through-via comprising at least a portion in the first semiconductor substrate, wherein the first through-via electrically connects the first metal pillar to the second metal pillar; and
the second die comprises a second semiconductor substrate and a second through-via comprising at least a portion in the second semiconductor substrate, wherein the second through-via electrically connects the third metal pillar to the fourth metal pillar.
